(19) United States
(12) Patent Application Publication
(10) Pub. No.: US 2020/0132736 A1
(43) Pub. Date: Apr. 30, 2020

(54) CURRENT SENSOR

(71) Applicant: TOYOTA JIDOSHA KABUSHIKI KAISHA, Toyota-shi (JP)

(72) Inventor: Hideaki FUJIOKA, Nisshin-shi (JP)

(73) Assignee: TOYOTA JIDOSHA KABUSHIKI KAISHA, Toyota-shi, Aichi (JP)

(21) Appl. No.: 16/576,941

(22) Filed: Sep. 20, 2019

(30) Foreign Application Priority Data
Oct. 30, 2018 (JP) 2018-203971

(51) Int. Cl. G01R 19/25; H02P 27/06

(52) U.S. Cl. CPC G01R 19/25; H02M 3/158; H02P 27/06

(57) ABSTRACT

A current sensor includes a sensor element configured to output a value of physical quantity depending on current supplied to a load; and a sensor controller configured to output a current value based on the output value of the sensor element. The sensor controller is configured to: acquire the output value and a temperature of the sensor element while current is not supplied to the load; determine a correlation between the output value and the temperature based on a plurality of sets of the acquired output value and the acquired temperature; calculate an offset of the output value at a temperature while current is supplied based on the correlation for the temperature of the sensor element; calculate the current value from a value obtained by subtracting the offset from the output value of the sensor element while current is supplied; and output the calculated current value.

### CROSS-REFERENCE TO RELATED APPLICATION

This application claims priority Japanese Patent Application No. 2018-203971 filed on Oct. 30, 2018, the contents of which are hereby incorporated by reference into the present application.

### TECHNICAL FIELD

The teaching disclosed herein relates to a current sensor. Especially, the teaching disclosed herein relates to a current sensor in which a temperature-dependent offset is included in an output value of a sensor element.

### BACKGROUND

There is a case where a temperature-dependent offset is included in an output value of a sensor element. A technique of learning the offset and obtaining an accurate current value is described for example in Japanese Patent Application Publication 2009-98091 (Patent Literature 1). The technique of Patent Literature 1 is adapted to an electric vehicle. The current sensor is provided with a smoothing capacitor connected to a power supply line and a sensor element configured to operate by receiving an electric power supply from the power supply line. The sensor element is configured to measure current that is supplied to a load. A controller of the current sensor acquires an output value of the sensor element while the current is not supplied to the load, and acquires a temperature of the smoothing capacitor. The controller stores the output value of the sensor element as a new offset when the acquired temperature is higher than a temperature acquired upon previous offset learning. From this moment on while the current is supplied to the load, the controller outputs a corrected current value obtained by subtracting the new offset from the output value of the sensor element.

### SUMMARY

In the technique of Patent Literature 1, the offset learning is performed only in cases of having a higher temperature than the temperatures acquired in the past offset learning. Due to this, the learning is not performed When the temperature is lower, thus a learning frequency decreases. Further, the temperature of the smoothing capacitor changes while the current is supplied to the load. In the technique of Patent Literature 1, the offset is maintained constant after the learning, thus it cannot address the changes in the temperature of the smoothing capacitor which take place after the learning. Further, the temperature of the smoothing capacitor differs from a temperature of the sensor element itself, thus there is a limit to accuracy in the offset learning based on the temperature of the smoothing capacitor. Especially with the electric vehicle, current that flows in a traction motor needs to be measured, and the sensor element is arranged in a vicinity of a bus bar in which large current for driving the traction motor flows. Heat from a switching element for power conversion may affect the sensor element via the bus bar. Improvement in the technique for cancelling temperature dependency of the sensor element is needed.

A current sensor disclosed herein may comprise a sensor element configured to output a value of physical quantity depending on current supplied to a load, and a sensor controller configured to output a current value based on the output value of the sensor element. A typical example of the value of physical quantity which the sensor element outputs is a voltage, but not limited thereto. The sensor controller may be configured to acquire the output value and a temperature of the sensor element while current is not supplied to the load. The sensor controller may be configured to determine a correlation between the output value and the temperature based on a plurality of sets of the acquired output value and the acquired temperature. The sensor controller may be configured to calculate an offset of the output value at a temperature of the sensor element while current is supplied to the load based on the correlation. The sensor controller may be configured to calculate the current value from a value obtained by subtracting the offset from the output value of the sensor element while current is supplied to the load. The sensor controller may be configured to output the calculated current value.

First of all, the current sensor disclosed herein does not limit learning performed while the current is supplied only to a case where the temperature is higher than that of previous learning. Due to this, a frequency of the learning increases, and accuracy of the offset is improved. Secondly, the sensor controller may determine the correlation between the output value (that is, the offset) and the temperature of the sensor element while the current is not supplied, and calculates the offset suitable for each temperature of the sensor element based on the correlation thereof. The offset is suitably changed depending on a temperature change in the sensor element while the current is supplied to the load. As a result of this, the current value which is more accurate than the conventional technique is outputted.

Details and further improvements of the technique disclosed herein will be described in DETAILED DESCRIPTION as below.

### BRIEF DESCRIPTION OF DRAWINGS

FIG. 1 is a block diagram of a power system of an electric vehicle including a current sensor of an embodiment.

FIG. 2 is a circuit diagram of a voltage converter and an inverter.

FIG. 3 is a bottom view of a power converter.

FIG. 4 is a front view of the power converter.

FIG. 5 is a diagram showing an internal structure of a terminal block.

FIG. 6 is a graph showing an example of temperature dependency of an output value of a Hall element.

FIG. 7 is a flowchart of an offset learning process.

FIG. 8 is a flowchart of a process to determine a correlation.

FIG. 9 is a flowchart of a current measuring process.

### DETAILED DESCRIPTION

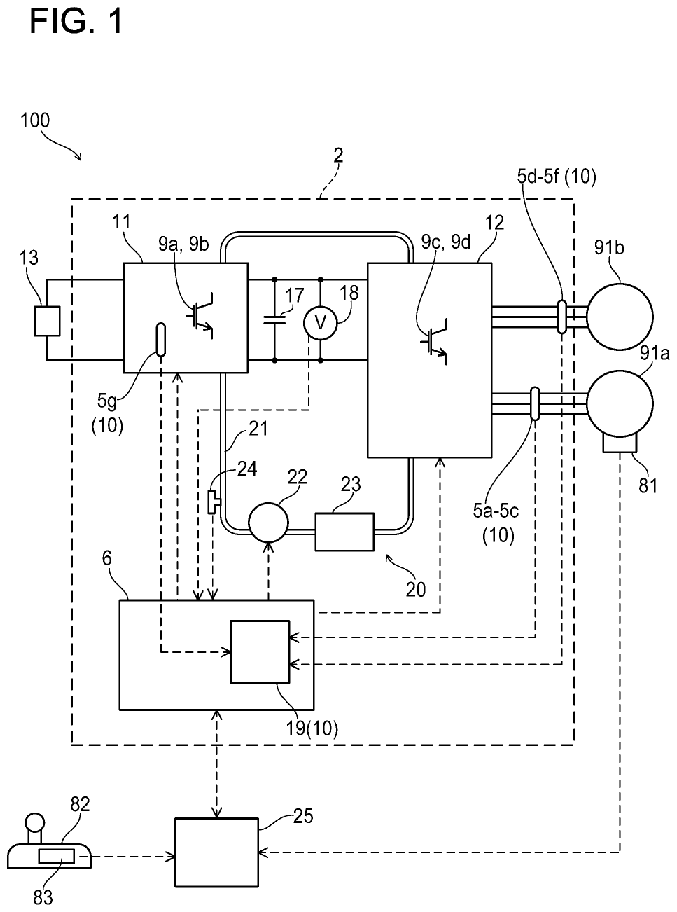

A current sensor 10 of an embodiment will be described with reference to the drawings. The current sensor 10 is mounted in an electric vehicle 100. More specifically, the current sensor 10 is provided in a power converter configured to convert outputted electric power of a DC power source to electric driving power for traction motors. FIG. 1 shows a block diagram of a power system of the electric vehicle 100 including a power converter 2 provided with the current sensor 10. The electric vehicle 100 includes two traction motors 91a, 91b for driving wheels.

Aside from the two traction motors 91a, 91b, the electric vehicle 100 is provided with a DC power source 13, a power converter 2, and a host controller 25. The DC power source 13 is a battery. The power converter 2 is configured to convert outputted electric power of the DC power source 13 to electric driving power for the traction motors 91a, 91b. The traction motors 91a, 91b are three-phase AC motors. The power converter 2 is configured to step up an output voltage of the DC power source 13 and convert the stepped-up electric power to three-phase alternating current. The current sensor 10 is configured to measure the three-phase alternating current which the power converter 2 outputs.

The power converter 2 is provided with a voltage converter 11, an inverter 12, a cooler 20, a traction motor controller 6, and the current sensor 10. The voltage converter 11 is a chopper-type bidirectional DC-DC converter, and is configured to step up the voltage of the DC power source 13 and supply the same to the inverter 12. The voltage converter 11 can also step down regenerated electric power which the traction motors 91a, 91b had generated (after having converted the same to DC power in the inverter 12) to the voltage of the DC power source 13.

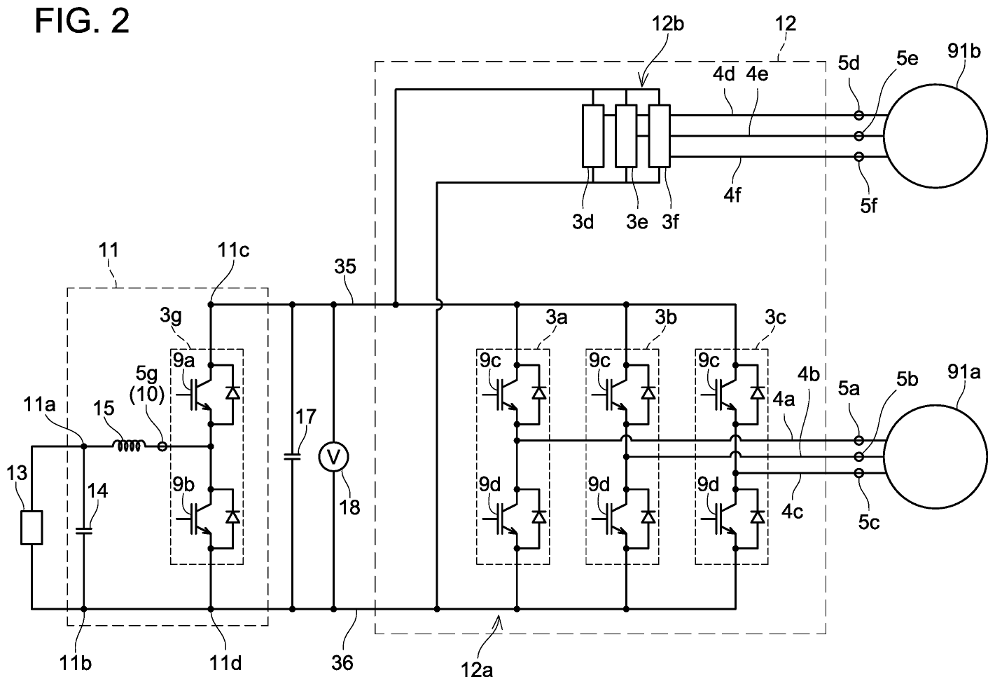

The chopper-type voltage converter 11 is provided with a plurality of switching elements 9a, 9b as well as a reactor and a capacitor. A circuit configuration of the voltage converter 11 will be described later with reference to FIG. 2. In FIG. 1, the voltage converter 11 is schematically depicted as being provided with the switching elements 9a, 9b and a Hall element 5g. The Hall element 5g constitutes the current sensor 10 together with a sensor controller 19. The Hall element 5g corresponds to a sensor element. The current sensor 10 is configured to measure current that flows in the reactor (described later). Further, as aforementioned, the current sensor 10 is configured to also measure the three-phase alternating current which the power converter 2 outputs.

Arrows with broken lines in the drawings show signal flows. An output of the Hall element 5g is sent to the sensor controller 19 in the traction motor controller 6. The traction motor controller 6 is configured to control the switching elements 9a, 9b based on measured data of the current sensor 10. The switching elements 9a, 9b are configured to operate according to commands from the fraction motor controller 6. A smoothing capacitor 17 and a voltage sensor 18 are provided on an output side of the voltage converter 11. The voltage sensor 18 is configured to measure an output voltage of the voltage converter 11 (an input voltage to the inverter 12). A measured value of the voltage sensor 18 is sent to the fraction motor controller 6.

The inverter 12 includes two sets of inverter circuits. Each of the inverter circuits is configured to convert DC power that has been stepped up by the voltage converter 11 to AC power for driving the traction motors 91a, 91b. A configuration of the inverter circuits will be described later with reference to FIG. 2. In FIG. 1, the inverter 12 is schematically depicted to show that it includes switching elements 9c, 9d. The switching elements 9c, 9d of the inverter 12 are also configured to operate according to commands from the traction motor controller 6.

Alternating current which the inverter 12 supplies to the traction motor 91a (91b) is measured by Hall elements 5a to 5c (5d to 5f) and the sensor controller 19. Outputs of the Hall elements 5a to 5f are also sent to the sensor controller 19 of the traction motor controller 6. The Hall elements 5a to 5g and the sensor controller 19 constitute the current sensor 10. The current sensor 10 will be described later in detail.

The traction motor controller 6 is configured to receive a target output command for the traction motors 91a, 91b from the host controller 25. The traction motor controller 6 is configured to perform feedback control of the switching elements 9a, 9b, 9c, 9d of the voltage converter 11 and the inverter 12 based on the measured values of the respective sensors so that the received target output command is realized. The host controller 25 is configured to determine a target output of the traction motors 91a, 91b from an accelerator position, vehicle speed, and a remaining charge in the DC power source 13, and send an command therefor (target output command) to the traction motor controller 6.

The host controller 25 has a revolution sensor 81 configured to measure a revolution of the traction motor 91a connected thereto. The revolution of the fraction motor 91a which, the revolution sensor 81 measures is sent to the host controller 25. The host controller 25 also has a gearshift lever 82 connected thereto. The gearshift lever 82 is provided with a position sensor 83 configured to detect a gearshift position of the gearshift lever 82. The gearshift position detected by the position sensor 83 is also sent to the host controller 25. Data of the revolution of the traction motor 91a and data of the gearshift position are also sent to the sensor controller 19 via the traction motor controller 6.

The power converter 2 is also provided with the cooler 20, and the cooler 20 is configured to cool the switching elements 9a, 9b of the voltage converter 11, the switching elements 9c, 9d of the inverter 12, the reactor of the voltage converter 11, and other devices. The cooler 20 is provided with a circulation passage 21 in which coolant flows, a radiator 23, a pump 22, and a temperature sensor 24. The circulation passage 21 passes through the voltage converter 11, the inverter 12, and the radiator 23. The switching elements 9a, 9b of the voltage converter 11 and the switching elements 9c, 9d of the inverter 12 are integrated as one unit, and the coolant is sent to this unit. The unit includes a plurality of cooling tubes (described later), and these cooling tubes correspond to a part of the circulation passage 21. The pump 22 is configured to send the coolant, which had passed through the radiator 23, to the cooling tubes. The temperature sensor 24 is configured to measure a temperature of the coolant before being sent to the cooling tubes. The coolant is water or antifreezing solution. The pump 22 is controlled by the traction motor controller 6. The traction motor controller 6 is configured to suitably control the pump 22 (that is, control a flow rate of the coolant) to prevent overheating of the switching elements 9a, 9b, 9c, 9d.

FIG. 2 shows a circuit diagram of the voltage converter 11 and the inverter 12. The voltage converter 11 is provided with the two switching elements 9a, 9b, two diodes, the reactor 15, and a filter capacitor 14. The two switching elements 9a, 9b are connected in series between a high-voltage positive terminal 11c and a high-voltage negative terminal 11d of the voltage converter 11. The diodes are connected in inverse parallel to the respective switching elements. The reactor 15 is connected between a low-voltage positive terminal 11a and a midpoint of a series connection of the two switching elements 9a, 9b. The Hall element 5g of the current sensor 10 is provided between the midpoint of the series connection and the reactor 15. The Hall element 5g is configured to measure a magnetic field generated by current flowing in the reactor 15. An output of the Hall element 5g is sent to the sensor controller 19 (see FIG. 1). The sensor controller 19 is configured to calculate the current flowing in the reactor 15 based on the output of the Hall element 5g and sends the same to the traction motor controller 6. That is, the current sensor 10 is configured to measure the current flowing in the reactor 15 (the current flowing in the voltage converter 11). The filter capacitor 14 is connected between the low-voltage positive terminal 11a and a low-voltage negative terminal 11b. The low-voltage negative terminal 11b and the high-voltage negative terminal 11d are connected directly. A broken line surrounding the two switching elements 9a, 9b and the diodes indicates a semiconductor module 3g. The semiconductor module 3g will be described later.

As aforementioned, the voltage converter 11 of FIG. 2 is a bidirectional DC-DC converter. Since the voltage converter 11 of FIG. 2 is well known, a description on an operation thereof will be omitted.

The inverter 12 is provided with two sets of inverter circuits 12a, 12b. The inverter circuit 12a will be described. The inverter circuit 12a has a circuit structure in which three sets of series connections of two switching elements 9c, 9d are connected in parallel. A diode is connected in inverse parallel to each of the switching elements 9c, 9d. Broken lines 3a to 3c each show a semiconductor module. Each of the semiconductor modules 3a to 3c accommodates the series connection of the two switching elements 9c, 9d and the diodes connected in inverse parallel to the respective switching elements 9c, 9d.

The three semiconductor modules 3a to 3c, that is, the three sets of the series connections of the switching elements 9c, 9d, are connected in parallel between a positive line (positive bus bar 35) and a negative line (negative bus bar 36). Alternating current is outputted from each of midpoints of the three sets of series connections. An output of the three sets of series connections, that is, output current of the inverter circuit 12a, is sent to the traction motor 91a via output bus bars 4a to 4c and a power cable (not shown). Bus bars are conductors suitable for transmitting large current. The bus bars are made for example of a copper plate.

The inverter circuit 12b has an identical structure as the inverter circuit 12a. Although not shown, a series connection of two switching elements 9c, 9d is accommodated in each of three semiconductor modules 3d to 3f. A diode is connected in inverse parallel to each of the switching elements 9c, 9d. Alternating current for driving the traction motor 91b is outputted from each of the midpoints of the three sets of series connections. Output current from each of the three sets of series connections is sent to the traction motor 91b via output bus bars 4d to 4f and a power cable that is not shown.

The Hall element 5a is disposed adjacent to the output bus bar 4a. Similarly, the Hall element 5b (5c) is disposed adjacent to the output bus bar 4b (4c). The Hall element 5a (5b, 5c) is configured to measure magnetic flux generated by current flowing in the output bus bar 4a (4b, 4c). More specifically, the Hall element 5a outputs a voltage depending on the magnetic flux which passes therethrough. The output (voltage) of the Hall element 5a is sent to the sensor controller 19 in the traction motor controller 6 (see FIG. 1). The sensor controller 19 is configured to calculate current that flows in the output bus bars 4a to 4c (that is, three-phase alternating current) based on the respective output values of the Hall elements 5a to 5c. Similarly, the Hall elements 5d to 5f are disposed adjacent to the output bus bars 4d to 4f respectively. The Hall elements 5d to 5f are configured to output voltages depending on magnetic flux generated by current flowing in the output bus bars 4d to 4f. The sensor controller 19 is configured to calculate current (that is, three-phase alternating current) that flows in the output bus bars 4d to 4f based on the respective output values of the Hall elements 5d to 5f. That is, the current sensor 10 is configured to measure the output current of the switching elements 9c, 9d.

The switching elements 9a to 9d are transistors for power conversion (power transistors). The switching elements 9a to 9d are for example Insulated Gate Bipolar Transistors (IGBTs).

3a to 3g of FIG. 2 show semiconductor modules. Hereinbelow, the term “semiconductor module 3” is used to refer to one of the semiconductor modules 3a to 3g without the need of distinction thereamong. Each semiconductor module 3 accommodates the two switching elements 9a, 9b (or 9c, 9d) and the diodes that are connected in inverse parallel to the respective switching elements. A main body of the semiconductor module 3 is a resin package, and the two switching elements 9a, 9b (or 9c, 9d) are connected in series within the resin package.

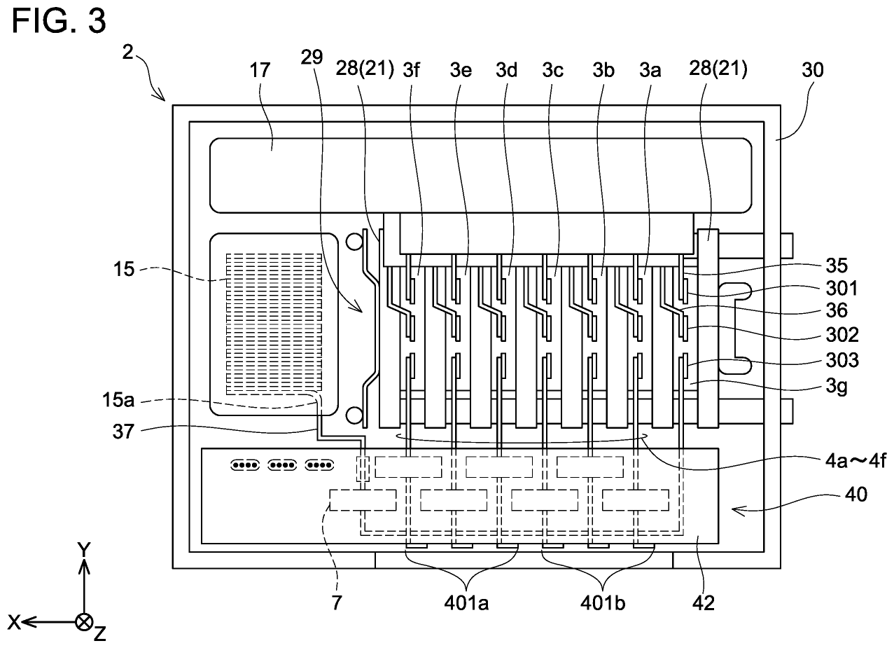

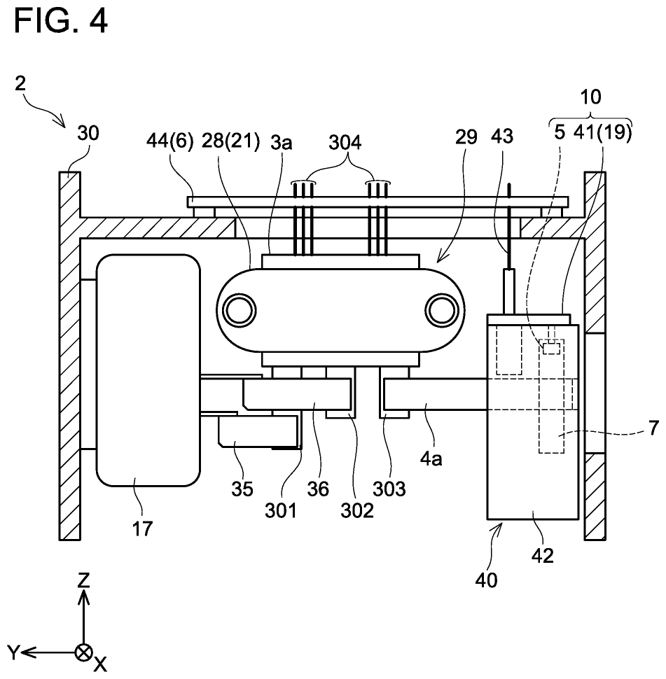

Next, a hardware configuration of the power converter 2 will be described with reference to FIGS. 3 to 5. FIG. 3 is a bottom view of the power converter 2, and FIG. 4 is a front view of the power converter 2. A bottom of a casing 30 is omitted in FIG. 3, and a front plate of the casing 30 is omitted in FIG. 4. In FIGS. 3 and 4, parts of the casing 30 are omitted so that a device layout inside the casing can be seen.

The plurality of semiconductor modules 3a to 3g accommodating the switching elements 9a, 9b (9c, 9d) configures a stack unit 29 together with a plurality of cooling tubes 28. In FIG. 3, reference sign 28 is given to the cooling tubes at both ends of the stack unit 29, and the reference sign is omitted for the rest of the cooling tubes. The cooling tubes 28 correspond to the circulation passage 21 of the cooler 20 which has been described earlier. The semiconductor modules 3a to 3g and the cooling tubes 28 are stacked alternately one by one, and the cooling tubes 28 contact each, of the semiconductor modules 3a to 3g from both sides thereof. The coolant flows inside the cooling tubes 28 to cool the semiconductor module 3 that is in contact with the cooling tubes 28.

A positive terminal 301, a negative terminal 302, an output terminal 303, and control terminals 304 extend from the main body of each semiconductor module 3. As aforementioned, the series connection of the two switching elements 9a, 9b (9c, 9d) is accommodated inside the main body of each semiconductor module 3. The positive terminal 301, the negative terminal 302, and the output tern al 303 are connected respectively to a positive side, a negative side, and the midpoint of the series connection of two switching elements 9a, 9b (9c, 9d). In FIG. 3, reference signs 301, 302, 303 are given only to the terminals of the semiconductor module 3g on the right end, and the reference signs indicating the terminals are omitted for other semiconductor modules 3a to 3f.

The control terminals 304 are connected to gates and sense emitters of the switching elements 9a, 9b (9c, 9d) inside the semiconductor module 3. Distal ends of the control terminals 304 are connected to a circuit board 44. The circuit board 44 has the traction motor controller 6 shown in FIG. 1 mounted thereon. The traction motor controller 6 is configured to control the switching elements 9a, 9b (9c, 9d) inside the semiconductor modulo 3 via the control terminals 304.

The smoothing capacitor 17 is adjacent to the stack unit 29 in a +Y direction in a coordinate system of the drawing. The reactor 15 is adjacent to the stack unit 29 in a +X direction in the coordinate system of the drawing.

The positive terminal 301 of each of the semiconductor modules 3a to 3g is connected to one electrode of the smoothing capacitor 17 by a positive bus bar 35, and the negative terminal 302 thereof is connected to the other electrode of the smoothing capacitor 17 by a negative bus bar 36. One end 15a of the reactor 15 is connected to the output terminal 303 of the semiconductor module 3g by an interconnecting bus bar 37. The output terminal 303 of the semiconductor module 3g corresponds to the midpoint of the series connection of the two switching elements 9a, 9b in the voltage converter 11 (see FIG. 2).

A terminal block 40 is adjacent to the stack unit 29 in a −Y direction in the coordinate system of the drawing. Corresponding one of output bus bars 4a to 4f is connected to each of the output terminals 303 of the semiconductor modules 3a to 3f A. main body 42 of the terminal block 40 is constituted of resin. The output bus bars 4a to 4f extend through the main body 42. Distal ends of the output bus bars 4a to 4c (4d to 4f) correspond to power terminals 401a (401b) on a side surface of the main body 42 of the terminal block 40. The semiconductor modules 3a to 3c configure the inverter circuit 12a, and the three-phase alternating current is outputted from the output terminals 303 of the semiconductor modules 3a to 3c. The power terminals 401a corresponding to the distal ends of the output bus bars 4a to 4c are connected to a power cable that is not shown. This power cable is connected to the traction motor 91a. The semiconductor modules 3d to 3f configure the inverter circuit 12b, and the three-phase alternating current is outputted from the output terminals 303 of the semiconductor modules 3d to 3f. The power terminals 401b corresponding to the distal ends of the output bus bars 4d to 4f are connected to another power cable that is not shown. This other power cable is connected to the traction motor 91b.

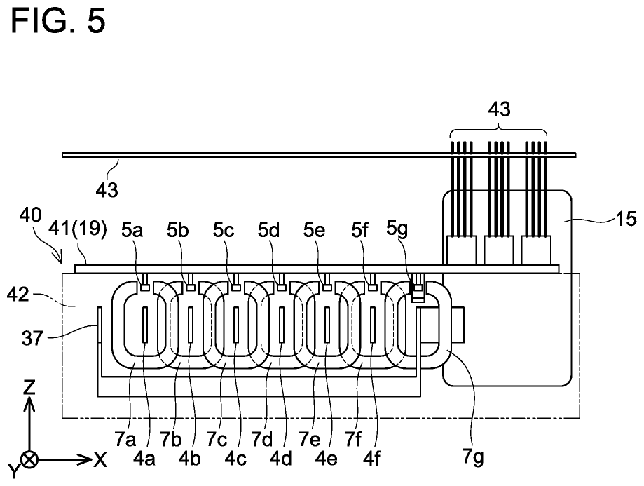

The Hall elements 5a to 5g as aforementioned are embedded inside the main body 42 of the terminal block 40. FIG. 5 shows an internal structure of the terminal block 40. In FIG. 5, the main body 42 of the terminal block 40 is depicted by a virtual line, and components inside the main body 42 are depicted by solid lines.

The current sensor 10 will be described. As aforementioned, the current sensor 10 is constituted of the Hall elements 5a to 5g and the sensor controller 19.

The output bus bars 4a to 4f and the interconnecting bus bar 37 extend through the main body of the terminal block 40. As shown in FIG. 5, the main body 42 of the terminal block 40 has the Hall elements 5a to 5g and ring cores 7a to 7g embedded therein. Each of the Hall elements 5a to 5f is disposed to be adjacent to its corresponding one of the output bus bars 4a to 4f. The Hall element 5g is disposed to be adjacent to the interconnecting bus bar 37. The ring core 7a surrounds the output bus bar 4a. A notch is provided in the ring core 7a, and the Hall element 5a is disposed within this notch, and the ring core 7a is constituted of a magnetic body. The ring core 7a is configured to collect magnetic flux generated by the current flowing in the output bus bar 4a. The magnetic flux collected by the ring core 7a penetrates through the Hall element 5a. The Hall element 5a is configured to output a voltage which depends on an intensity of the magnetic flux. The Hall element 5a is connected to a sensor substrate 41. The sensor substrate 41 has mounted thereon a circuit (sensor controller 19) configured to convert the voltage outputted by the Hall element 5a to a magnitude of the current flowing in the output bus bar 4a.

The same applies to the Hall elements 5b to 5f, the ring cores 7b to 7f, and the output bus bars 4b to 4f. In summary, each of the Hall elements 5a to 5f is configured to output a voltage depending on current flowing in its corresponding one of the output bus bars 4a to 4f. Similarly, the Hall element 5g is configured to output a voltage depending on current flowing in the interconnecting bus bar 37. The sensor controller 19 is configured to calculate the current flowing respectively in the output bus bars 4a to 4f and the interconnecting bus bar 37 based on the output values of the Hall elements 5a to 5g, and output the same to the traction motor controller 6.

Hereinbelow for the sake of convenience of explanation the term “output bus bar 4” is used to refer to one of the output bus bars 4a to 4f. The Hall element corresponding to this output bus bar 4 is termed the “Hall element 5”. The semiconductor module to which this output bus bar 4 is connected is termed the “semiconductor module 3”, and the switching elements accommodated in this semiconductor module 3 are termed the “switching elements 9”. Explanation on the interconnecting bus bar 37 and the Hall element 5g will be omitted. Further, hereinbelow, the traction motor (which is one of the traction motors 91a and 91b) connected to this output bus bar 4 is termed the “traction motor 91”.

The switching elements 9 are configured to convert the outputted electric power of the DC power source 13 to the electric driving power of the traction motor 91. The outputted current of the switching elements 9 flows through the output bus bar 4. The Hall element 5 is arranged inside the main body 42 of the terminal block 40 so as to be adjacent to the output bus bar 4. Heat from the switching elements 9 is transmitted to the Hail element 5 via the output bus bar 4. As such, when a load on the switching elements 9 is large, heat generation thereof increases accordingly, by which a temperature of the Hall element 5 increases. A bias voltage is applied in advance to an input terminal of the Hall element 5, and a voltage at an output terminal changes according to the intensity of the magnetic flux that passes through the Hall element 5. However, a certain voltage is outputted even when the magnetic flux is zero (that is, when no current is flowing in the output bus bar 4). The output voltage of the Hall element 5 while no current is flowing in the output bus bar 4 corresponds to an offset. An output voltage corresponding to the current flowing in the output bus bar 4 is obtained by subtracting the offset from the output voltage of the Hall element 5 while the current is flowing in the output bus bar 4.

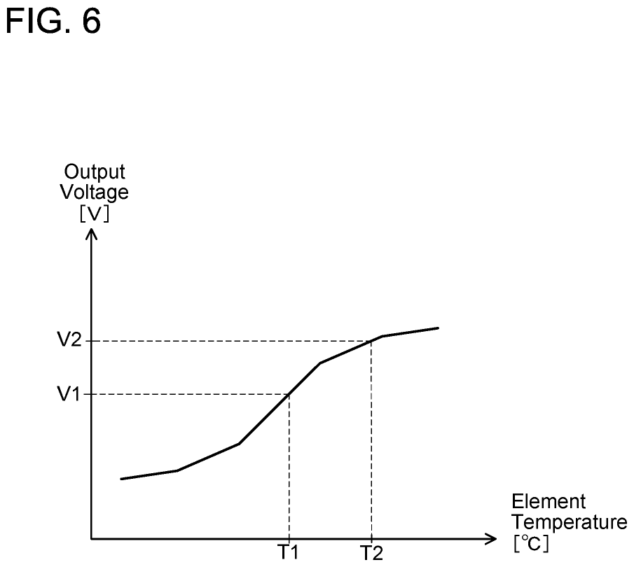

FIG. 6 shows an example of temperature dependency of the output voltage of the Hall element 5. FIG. 6 shows the output voltage of the Hall element 5 when no current is flowing in the output bus bar 4. For example, when a temperature of the Hail element 5 is at a temperature T1, the output voltage of the Hall element 5 is at a voltage V1, however, when the temperature of the Hall element 5 rises to a temperature T2, the output voltage changes to a voltage V2. As above, the output voltage of the Hall element 5 while no current is flowing in the output bus bar exhibits the temperature dependency. Thus, the current sensor 10 determines a correlation (that is, the offset) between the temperature and the output voltage of the Hall element 5 when no current is flowing in the output bus bar. The sensor controller 19 uses the determined correlation to decide the offset at an element temperature when the current is flowing in the output bus bar 4, and calculates the current of the output bus bar 4 based on a value which subtracted the offset from the output voltage of the Hall element 5 (i.e., a value obtained by subtracting the offset from the output voltage of the Hall element 5) at that timing. “While no current is flowing in the output bus bar 4” has a same meaning as “while current is not supplied to the traction motor 91, which is a load”. “While the current is flowing in the output bus bar 4” has a same meaning as “while current is supplied to the traction motor 91, which is the load”.

The temperature of the Hall element 5 may be measured by providing a temperature sensor on the Hall element 5. However, in the current sensor 10 of the embodiment, the temperature of the Hall element 5 is estimated from the current supplied to the fraction motor 91 (the current that flows in the traction motor 91), the measured value of the temperature sensor 24 which measures the temperature of the coolant of the cooler 20, and the measured value of the voltage sensor 18 which measures the voltage in the power converter 2. The measured temperature of the temperature sensor 24 has a positive correlation with a temperature of the switching elements 9. Further, the current which is supplied to the traction motor and the internal voltage of the power converter 2 also have positive correlations with the temperature of the switching elements 9. Further, there also is a positive correlation between the temperature of the switching elements 9 and the temperature of the Hall element 5. These correlations are obtained in advance by experiments and/or evaluation tests. The sensor controller 19 stores the correlations of the current supplied to the traction motor, the measured values of the temperature sensor 24 and the voltage sensor 18, and the temperature of the Hall element 5. The sensor controller 19 uses these correlations to estimate the temperature of the Hall element 5 from respective types of sensor data. For the convenience of explanation, the temperature of the Hall element 5 is termed the “element temperature” hereinbelow.

Due to the dependency of the offset to the element temperature, the sensor controller 19 learns the temperature dependency of the offset while the vehicle is stopped. Further, in a current measuring process performed while the vehicle is traveling, the sensor controller 19 calculates the offset based on the present element temperature and subtracts the offset from the output voltage of the Hall element 5. The sensor controller 19 calculates the current value based on the output voltage of the Hall element 5 from which the offset, to which the consideration on the temperature dependency has been given, has been subtracted. Since the offset is decided based on the element temperature at the time of measuring the current, an accurate current value can be obtained even if the element temperature changes while the vehicle is traveling.

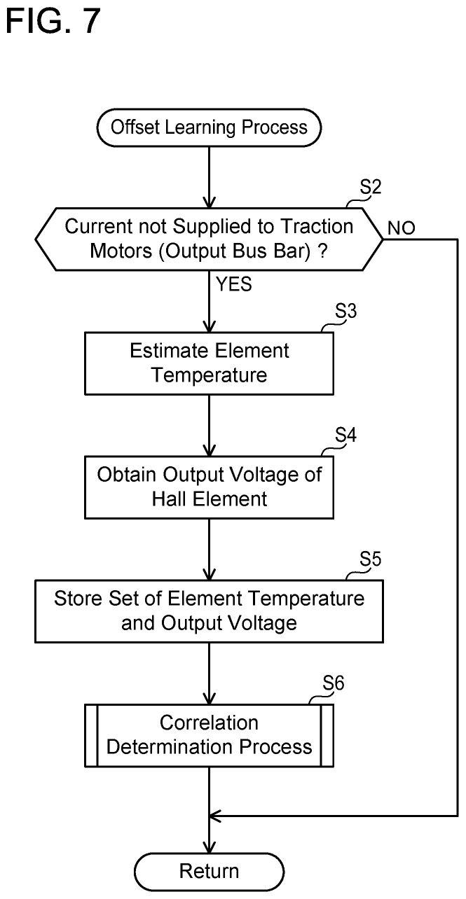

FIG. 7 shows a flowchart of the offset learning process. The process of FIG. 7 is performed periodically by the sensor controller 19. The sensor controller 19 firstly checks whether or not current is supplied to the traction motor 91 (output bus bar 4) (step S2). The sensor controller 19 determines as that no current is supplied to the traction motor 91 in a case where the revolution (rotational speed) of the traction motor 91 is zero and the gearshift position is in one of P position (parking position) and N position (neutral position). The revolution of the traction motor 91 is measured by the revolution sensor 81 (see FIG. 1), and is sent to the sensor controller 19 via the host controller 25. The gearshift position is detected by the position sensor 83 (see FIG. 1), and is sent to the sensor controller 19 via the host controller 25. A situation may arise in which the current is supplied to the traction motor 91 even though the revolution is zero, such as when the wheels are riding over a wheel stopper despite an accelerator being stepped on. As such, the sensor controller 19 employs the gearshift position being in one of the P position and the N position as its condition for determining that no current is supplied to the fraction. motor 91.

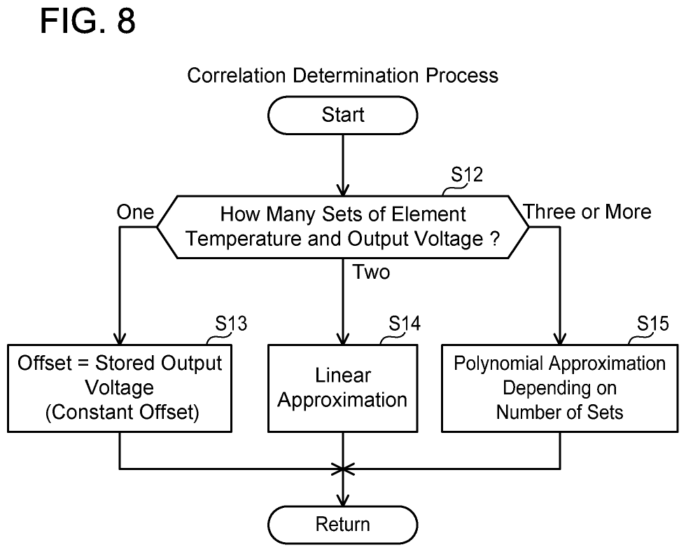

The offset learning is not performed. While the current is supplied to the traction motor 91 (step S2: NO). The learning process is performed from step S3 to step S6 while the current is not supplied to the traction motor 91. The sensor controller 19 estimates the temperature of the Hall element 5 (step S3). The method of temperature estimation is as discussed earlier. Next, the sensor controller 19 obtains the output voltage of the Hall element 5 (step S4). Then, the sensor controller 19 stores a pair of the element temperature estimated in step S3 and the output voltage obtained in step S4 (step S5). Next, the sensor controller 19 determines the correlation between the element temperature and the offset (step S6). A correlation determining process is shown in FIG. 8. Hereinbelow, the pair of the element temperature and the output voltage is termed a “dataset”.

The sensor controller 19 performs the process of determining the relationship between the element temperature and the offset (step S6) from stored dataset(s). FIG. 8 shows a flowchart of a process of determining the relationship between the element temperature and the offset.

The sensor controller 19 may determines the correlation between the element temperature and the offset by using different algorithms depending on a number of the stored dataset(s). In a case where only one dataset is stored, the output voltage of this set is determined as the offset (step S1). Since there is only one dataset, the offset is constant regardless of the temperature.

In a case where two datasets are stored, the sensor controller 19 performs linear approximation of the correlation between the element temperature and the offset from those two datasets (step S14). In a case where three or more datasets are stored, the sensor controller 19 performs polynomial approximation of the correlation between the element temperature and the offset according to the number of datasets. The correlation of the offset relative to the element temperature is determined as above. A value of the offset relative to the element temperature becomes more accurate as the number of the datasets increases. Here, the polynomial approximation is used for the case where three or more datasets are stored. However, the correlation between the element temperature and the offset may be determined by the linear approximation for all eases where the number of the datasets is two or more.

The processes of FIGS. 7 and 8 are performed periodically. The processes of FIGS. 7 and 8 may be performed each time the vehicle stops at a signal, for example. The number of the datasets increases every time the processes of FIGS. 7 and 8 are executed, by which the learning is enhanced, and the offset becomes more accurate.

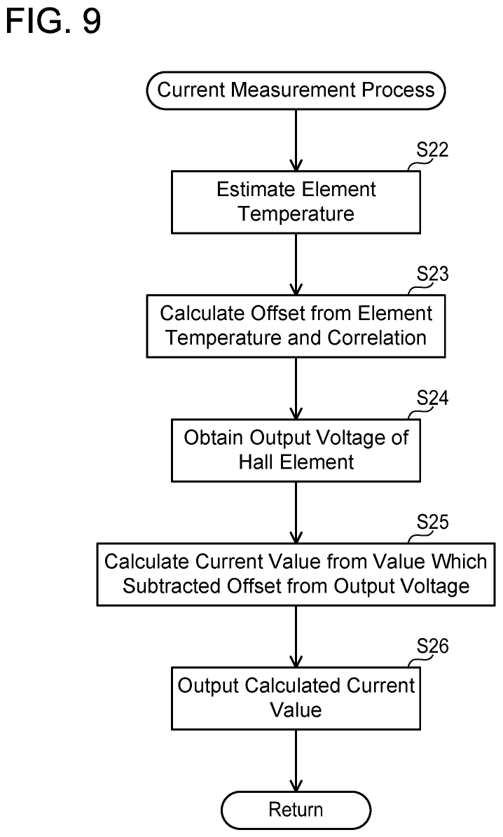

FIG. 9 shows a flowchart of how the offset is used, that is, the current measuring process performed while the vehicle is traveling. The sensor controller 19 performs the process of FIG. 9 periodically while the vehicle is traveling. The sensor controller 19 estimates the temperature of the Hall element 5 (element temperature) (step S22). The method of estimation is as discussed earlier. Next, the sensor controller 19 calculates the present offset (latest offset) from the element temperature and the correlation thereof (step S23). Next, the sensor controller 19 obtains the output voltage of the Hall element (step S24). Next, the sensor controller 19 calculates the current value from the value which subtracted the offset (present offset) from the output voltage. There is a proportional relationship between the output voltage after having subtracted the offset and the current flowing in the output bus bar. Due to this, the sensor controller 19 obtains the current value by multiplying a proportional coefficient to the output voltage from which the offset has been subtracted. Finally, the sensor controller 19 outputs the calculated current value to the traction motor controller 6 (step S26).

The current sensor 10 described in the embodiment determines the correlation of the offset relative to the element temperature from the element temperature and the output voltage obtained while the current is not supplied to the traction motor. The sensor controller 19 calculates the offset based on the latest element temperature and subtracts the offset from the output voltage of the Hall element while the current is supplied to the traction motor. Since the offset according to the latest element temperature is used, the current sensor 10 has high current measurement accuracy. The power converter 2 controls the traction motors 91a, 91b based on the output of the current sensor 10. The traction motors 91a, 91b are three-phase AC traction motors. Control of the traction motors becomes inaccurate with an inaccurate offset of the current sensor 10, as a result of which rotations of the traction motors 91a, 91b may thereby be pulsated. Pulsation in the rotations of the traction motors 91a, 91b causes pulsation in gearsets coupled to the traction motors 91a, 91b. The pulsation in the gearsets may become a cause of noise and vehicle vibration. The electric vehicle 100 using the current sensor 10 of the embodiment can suppress noise and vehicle vibration caused by inaccuracy of the offset.

Some features related to the technique described in the embodiment will be described. The traction motor 91a (or the traction motor 91b) is an example of a load. The current sensor 10 is configured to measure current supplied to the load (that is, the traction motor 91a or 91b). The Hall elements 5a to 5g are examples of a sensor element. In the embodiment, the sensor controller 19 is configured to estimate the temperatures of the Hall elements based on the current supplied to the traction motors and the voltage in the power converter. In the current sensor disclosed herein, temperature sensor(s) configured to measure temperature(s) of the sensor element(s) may be provided.

In an example of the current sensor disclosed herein, the current sensor is mounted in a vehicle, and load(s) thereof are fraction motor(s). The sensor controller may he configured to acquire temperature(s) and an output value of a sensor element when a gearshift position of the vehicle is in one of P position and N position and the revolution(s) of the traction motor(s) are zero, and to determine the aforementioned correlation. According to such a configuration, the current flowing in the traction motor(s) can accurately be measured. The “P position” refers to a state in which a parking brake is actuated, and the “N position” refers to a neutral state, that is, a state in which the fraction motor(s) (and an engine) are disconnected from wheel(s).

Specific examples of the present invention have been described in detail, however, these are mere exemplary indications and thus do not limit the scope of the claims. The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

What is claimed is:

1. A current sensor comprising:
a sensor element configured to output a value of physical quantity depending on current supplied to a load; and
a sensor controller configured to output a current value based on the output value of the sensor element,
wherein the sensor controller is configured to:
acquire the output value and a temperature of the sensor element while current is not supplied to the load;
determine a correlation between the output value and the temperature based on a plurality of sets of the acquired output value and the acquired temperature;
calculate an offset of the output value at a temperature of the sensor element while current is supplied to the load based on the correlation;
calculate the current value from a value obtained by subtracting the offset from the output value of the sensor element while current is supplied to the load; and
output the calculated current value.

2. The current sensor of claim 1, wherein
the current sensor is mounted on a vehicle,
the load is a traction motor, and
the sensor controller is configured to acquire the output value and the temperature of the sensor element under a condition that a gearshift position of the vehicle is in one of P position and N position and a revolution of the traction motor is zero.

3. The current sensor of claim 2, wherein
the current sensor is provided with a power converter configured to convert electric power of a power source to electric driving power of the traction motor,
the vehicle is provided with a temperature sensor configured to measure a temperature of coolant which cools the power converter, and
the sensor controller is configured to estimate the temperature of the sensor element based on current supplied to the fraction motor, a measured value of the temperature sensor, and a voltage in the power converter.
